(19) United States
(12) Patent Application Publication
(10) Pub. No.: US 2006/0073681 A1
(43) Pub. Date: Apr. 6, 2006

(54) Nanoheteroepitaxy of Ge on Si as a foundation for group III-V and II-VI integration

(76) Inventor: Sang M. Han, Albuquerque, NM (US)

Correspondence Address: MIN, HSIEH & HACK LLP, 8270 GREENSBORO DRIVE, SUITE 630, MCLEAN, VA, 22102, US

(21) Appl. No.: 11/260,231

(22) Filed: Oct. 28, 2005

Related U.S. Application Data
(63) Continuation-in-part of application No. 10/935,228, filed on Sep. 8, 2004.
(60) Provisional application No. 60/622,688, filed on Oct. 28, 2004.

(51) Int. Cl. H01L 21/20; H01L 21/36

(52) U.S. Cl. 438/479

(57) ABSTRACT

A method of forming a virtually defect free lattice mismatched nanoheteroepitaxial layer is disclosed. The method includes forming an interface layer on a portion of a substrate. The interface layer can be, for example, SiO₂, Si₃N₄, Al₂O₃, or W. A template can then be made by forming a plurality of touchdown windows in the interface layer. A plurality of seed pads can then be formed in the touchdown windows by exposing the interface layer to a material comprising a semiconductor material. The plurality of seed pads, having an average width of about 1 nm to 10 nm, can be interspersed within the interface layer and contact the substrate. A first layer is formed by lateral growth of the seed pads over the interface layer. A second layer is then formed on the first layer. The second layer can be for example, one of a Group III-V and II-VI heteroepitaxial film.

### CROSS-REFERENCE TO RELATED APPLICATIONS

This application is a continuation-in-part of U.S. patent application Ser. No. 10/935,228 filed on Sep. 8, 2004, and claims priority to. U.S. Provisional Patent Application Ser. No. 60/622,688 filed on Oct. 28, 2004, the disclosures of which are incorporated by reference in their entirety.

### FIELD OF THE INVENTION

The present invention relates to semiconductor devices and methods for their manufacture and, more particularly, relates to epitaxial growth of lattice mismatched systems.

### BACKGROUND OF THE INVENTION

Conventional semiconductor device fabrication is generally based on growth of lattice-matched layers. A lattice mismatched epitaxial layer at a semiconductor interface can lead to a high density of dislocations that degrade semiconductor device performance. Over the past several years, however, there has been increased interest in epitaxial growth of lattice-mismatched semiconducting material systems. Lattice mismatched systems can provide a greater range of materials characteristics than silicon. For example, the mechanical stress in a lattice mismatched layer and control of its crystal symmetry can be used to modify the energy-band structure to optimize performance of optoelectronic devices. Comprehensive materials engineering solutions are also needed to integrate high-quality Group III-V and II-VI heteroepitaxial films on Si. For example, lattice mismatched systems can enable compound semiconductor devices to be integrated directly with Si-based complementary metal oxide semiconductor (CMOS) devices. This capability to form multifunction chips will be important to the development of future optical and electronic devices.

Problems arise, however, because an epitaxial layer of a lattice-mismatched material on a substrate is often limited to a critical thickness (h_{c}), before misfit dislocations begin to form in the expitaxial material. For example, h_{c}=2 nm for a germanium epitaxial layer on a silicon substrate. Because of the relatively small h_{c} and the large dislocation densities at thicknesses greater than h_{c}, use of the heteroepitaxial layer is impractical. Conventional solutions include multiple post-growth annealing, liquid-phase epitaxy, epitaxial necking, and graded layers. Conventional solutions, however, require intricate patterning and/or high processing temperatures that can increase fabrication cost and complexity.

Thus, there is a need to overcome these and other problems of the prior art and to provide a method to grow high-quality heteroepitaxial layers of lattice mismatched systems.

### SUMMARY OF THE INVENTION

According to various embodiments, the present teachings include a method of forming a semiconductor device. The method can include forming an interface layer on a substrate and forming a plurality of touchdown windows in the interface layer. The touchdown windows can be formed using interferometric lithography such that each of the touchdown windows expose a portion of the substrate. The exposed portions of the substrate can then be exposed to a material comprising a semiconductor material to form an island comprising the semiconductor material on each of the exposed portions of the substrate.

According to various other embodiments, the present teachings include another method of forming an epitaxial overgrowth layer. The method can include forming an interface layer on a substrate and using interferometric lithography to form a periodic pattern on the interface layer. The periodically patterned interface layer can be plasma etched to form a template that exposes portions of the substrate. Germanium islands can be selectively grown on the substrate through openings of the template using molecular beam epitaxy. The germanium islands can then coalesce to form a single crystal expitaxial overgrowth layer.

According to various other embodiments, the present teachings can include a semiconductor device. The semiconductor device can include a substrate and a template disposed on the substrate, wherein the template comprises a periodic pattern that exposes portions of the substrate. An epitaxial layer can be disposed over the template and can contacting the exposed portions of the substrate. The semiconductor device can further include a layer disposed on the epitaxial layer, wherein the layer comprises at least one element from Groups III-V and II-VI.

It is to be understood that both the foregoing general description and the following detailed description are exemplary and explanatory only and are not restrictive of the invention, as claimed.

The accompanying drawings, which are incorporated in and constitute a part of this specification, illustrate several embodiments of the invention and together with the description, serve to explain the principles of the invention.

### BRIEF DESCRIPTION OF THE DRAWINGS

FIG. 1 depicts a cross-sectional view of an interface layer on a substrate in accordance with exemplary embodiments of the invention.

FIG. 2A depicts a cross-sectional view of seed pad sites or “touchdown windows” interspersed in an interface layer in accordance with exemplary embodiments of the invention.

FIG. 2B depicts a top-down view of seed pad sites interspersed in an interface layer in accordance with exemplary embodiments of the invention.

FIG. 3 depicts a cross-sectional view of seed pads on a substrate and separated by portions of the interface layer in accordance with exemplary embodiments of the invention.

FIG. 4 depicts a cross-sectional view of seed pad growth over the top of the interface layer in accordance with exemplary embodiments of the invention.

FIG. 5 depicts a cross-sectional view of a semiconductor layer formed by lateral growth of seed pads over portions of the interface layer in accordance with exemplary embodiments of the invention.

FIG. 6 depicts a cross-sectional view of a second semiconductor layer on the semiconductor layer in accordance with exemplary embodiments of the invention.

FIG. 7 depicts a top-down view of a template including an array of touchdown windows formed by interferometric lithography in accordance with exemplary embodiments of the invention.

FIG. 8 depicts a cross-sectional view of a template including touchdown windows formed by interferometric lithography in accordance with exemplary embodiments of the invention.

FIG. 9 depicts a cross-sectional view of island growth over the top of the template in accordance with exemplary embodiments of the invention.

FIG. 10 depicts a cross-sectional view of the semiconductor layer formed by lateral overgrowth of the islands over the template and another layer disposed on the semiconductor layer.

FIG. 11 depicts a cross-sectional view of island growth within the touchdown windows of the template and another layer disposed on the template and islands.

### DESCRIPTION OF THE EMBODIMENTS

In the following description, reference is made to the accompanying drawings that form a part thereof, and in which is shown by way of illustration specific exemplary embodiments in which the invention may be practiced. These embodiments are described in sufficient detail to enable those skilled in the art to practice the invention and it is to be understood that other embodiments may be utilized and that changes may be made without departing from the scope of the invention. The following description is, therefore, not to be taken in a limited sense.

As used herein, the term “self-directed touchdown” refers to a nucleation and growth process that is initiated without reliance on a photolithographic mask to pattern a substrate or other layer.

As used herein, the term “nanoheteroepitaxy” refers to engineering a heterojunction at the nanoscale to relieve lattice strain.

As used herein, the terms “epitaxial layer” and “epilayer” are used interchangeably to refer to a layer grown upon an underlying layer, where the layer has the same crystalline orientation as the underlying layer. The underlying layer can be, for example, a substrate.

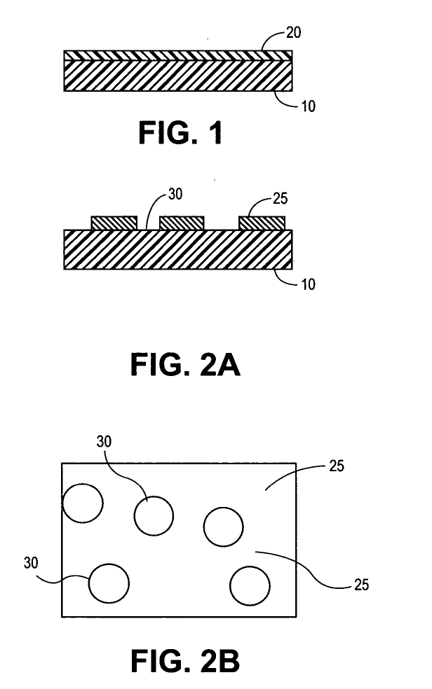

FIGS. 1-11 depict exemplary embodiments of devices and methods for making the devices that include a high-quality epilayer on a substrate. According to various embodiments, the exemplary methods and devices can include a substrate and an interface layer with a plurality of touchdown windows. The exemplary methods and devices can further include a seed pad formed by self-directed touchdown within each touchdown window. According to various other embodiments, the exemplary methods and devices can include a substrate and template with a plurality of touchdown windows that expose a portion of the substrate. The exemplary methods and devices can further include an epitaxial layer over the template formed by coalescence of islands nucleated and grown within the touchdown windows.

Referring to FIG. 1, a substrate 10 is shown. Substrate 10 can be, for example, a silicon substrate. Other substrate materials can include any semiconductor material having a lattice-mismatch to a desired epitaxial layer. The terms “lattice-mismatch” and “lattice-mismatched material” as used herein refer to two or more materials whose lattice parameters in a given crystalline plane or direction are not identical. Lattice-mismatched materials can include, but are not limited to, silicon and germanium, silicon and carbon, silicon and GaAs, silicon and InP, and silicon and gallium nitride.

An interface layer 20 can be formed on substrate 10. Interface layer 20 can be, for example, an oxide layer, such as, a SiO₂ layer, having a thickness of about 1 Å to about 30 Å. The SiO₂ layer can be formed by methods known in the art, such as, for example, treating substrate 10 in a Piranha solution or by thermal growth. Other interface materials can include, but are not limited to, Si₃N₄, Al₂O₃, and W. In various embodiments, interface layer 20 can comprise an amorphous material.

In various embodiments, properties of interface layer 20, such as surface roughness and thickness, can be controlled to tailor the defect morphology of the epitaxial layer. For example, interface layer 20 can be formed using H₂O₂ to achieve a monolayer of atomically flat SiO₂ on a hydrogenated Si(100) substrate.

After forming interface layer 20 on substrate 10, interface layer 20 can be exposed to a material comprising a semiconductor material. Exposure temperatures can be about 500°0 C. to about 750° C. The semiconductor material can comprise, for example, germanium (Ge). In various embodiments, molecular beam epitaxy can be used to expose interface layer 20 to Ge. As shown in cross-sectional view of FIG. 2A and the top view of FIG. 2B, the Ge can react with interface layer 20, to form interface layer free areas 30 also referred to as “touchdown windows.” Interface free areas 30 serve as touchdown windows exposing portions of substrate 10.

While not intending to be bound by any particular theory, it is believed that interface layer free areas 30 can form through reaction of the Ge with the oxide film as follows: SiO2(s)+Ge(ad)→SiO(g)+GeO(g). Ge can also diffuse through the pinholes or other defects that exist in the interface layer and react with SiO₂ in the presence of Si: Si+2SiO₂(s)+Ge(ad)→GeO(g)+3SiO(g). Instead of indiscriminately removing a large area of the SiO₂, the reaction between Ge and SiO₂ can take place in a self-limiting fashion with a well-defined surface density and inter-distance. Interface layer free areas 30 can be randomly distributed to form a remaining portion of interface layer 25, and can be about 2 nm to about 8 nm wide. The spacing between interface layer free areas can be about 2 nm to about 14 nm.

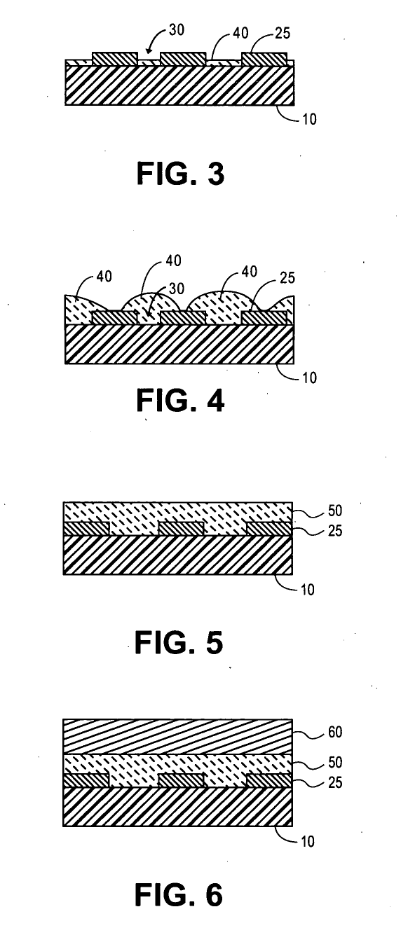

As exposure to Ge continues, the Ge can deposit in interface layer free areas 30. There is generally no deposition on remaining portions of interface layer 25, due to selective deposition. This self-directed touch-down of Ge on Si occurs without lithography to pattern the substrate or interface layer. The regions of Ge growth on Si substrate 10 can form crystalline Ge islands, referred to herein as seed pads 40, shown in FIG. 3. As shown in FIG. 4, seed pads 40 can then laterally overgrow and coalesce, as exposure to Ge continues. As lateral growth of Ge seed pads 40 over remaining oxide layer 25 continues, Ge seed pads 40 coalesce into a single semiconductor layer 50 as shown in FIG. 5. The semiconductor layer 50 can be a virtually defect free single crystalline epitaxial lateral overgrowth (ELO) layer.

While not intending to be bound by any particular theory, it is believed that selective growth of Ge on Si and over SiO₂ results from a different mechanism than the reaction between Ge and SiO₂ forming volatile monoxide products. For example, the desorption activation energy (E_{d}) of Ge from SiO₂ is approximately 42±3 kJ/mol, on the order of Van der Waals forces rather than a strong chemical bond. The selectivity of Ge on Si over SiO₂ is dominated by the low desorption activation energy of Ge adspecies on the SiO₂ surface. At the growth temperature, the low desorption activation energy can give rise to a high desorption flux. When the Ge impingement flux is less than the desorption flux, Ge adspecies evaporate before forming stable nuclei. If the surface temperature is decreased, the desorption flux of Ge adspecies decreases exponentially. When the impingement flux exceeds the desorption flux, net Ge adspecies on the surface leads to formation of stable islands. One of ordinary skill in the art understands that formation of a Ge epilayer on a Si substrate is disclosed for further understanding of the exemplary methods and that other layers can be formed on other substrates.

FIG. 5 shows a semiconductor layer 50 formed by coalesced seed pads 40 having an atomically abrupt interface with substrate 10. Semiconductor layer 50 can be virtually defect-free having a threading dislocation density of about 1×10⁵ cm⁻² or less. Stacking faults can exist over the remaining oxide layer patches 25, but generally terminate within about 80 nm from the interface, for example, the SiO₂-Ge interface. The thickness of semiconductor layer 50 can be greater than the critical thickness h_{c}, for example, greater than the critical thickness of 2 nm for 100% Ge on Si. Seed pads 40 can have an average width of about 1 nm to 10 nm. The distance between seed pads can be about 3 nm or more.

According to various embodiments and referring to FIG. 6, a second semiconductor layer 60 can be deposited over semiconductor layer 50. The second semiconductor layer 60 can comprise one or more materials from Group III- VI and II-VI, such as, for example, GaN, GaAs, AlGaAs, InGaP, AlInP, AlInGaP, InGaAsN, SiGe, and HgCdTe.

### EXAMPLE 1

In an exemplary embodiment, a Ge epilayer was formed on a silicon substrate using the methods disclosed herein. Referring back to FIGS. 1, 2A, and 3, substrate 10 was a silicon substrate formed by dicing undoped Si(100) and Si(111) wafers. Contaminants were removed from the surface of silicon substrate 10 by immersion in a Piranha solution for about 5 minutes. The Piranha solution was prepared by mixing 4 volumetric parts of 2M H₂SO₄ with 1 volumetric part of 30 wt % H₂O₂. Because the Piranha solution is an oxidant, a SiO₂ layer formed on silicon substrate 10. The SiO₂ layer was then removed by an 11 wt % HF solution. The HF solution was prepared by diluting a 49 wt % HF solution to 11 wt % using deionized H₂O. The Piranha and HF solution treatments were each repeated three times.

A SiO₂ layer 20 was then formed on silicon substrate 10. SiO₂ layer 20 was formed by chemical oxidation by immersion of silicon substrate 10 in a fresh Piranha solution for about 10 minutes at about 80° C. The thickness of SiO₂ layer 20 was about 1.2 nm. SiO₂ layer 20 was rinsed with deionized water, dried with N₂ gas, and placed in an ultrahigh vacuum (UHV) molecular beam epitaxy (MBE) chamber. The base pressure of the UHV chamber was about 4×10⁻¹⁰ Torr. After heating substrate 10 to about 510° C. to about 620° ° C., a Ge flux of about 0.24 equivalent monolayers per second was provided by a Ge Knudsen effusion cell operated at about 1200° C. The Ge exposure created a plurality of touchdown windows 30 in SiO₂ layer 20 having a width of about 3 nm to about 7 nm. Continued exposure to Ge resulted in the formation of Ge seed pads 40 within touchdown windows 30. Ge seed pads 40 had a density exceeding about 10¹¹cm⁻². The inter-touchdown window distance was about 2 nm to about 12 nm.

Further exposure to Ge resulted in the seed pads 40 growing over the top of touchdown windows 30 and coalescing into Ge epilayer 50, for example, as shown in FIGS. 4 and 5. Ge epilayer 50 was a fully relaxed, single crystalline layer having a dislocation density of less than about 10⁵ cm⁻².

In various other embodiments, an epilayer can be formed using a template formed in the interface layer by interferometric lithography. Referring back to FIG. 1, an interface layer 20 can be disposed on a substrate 10. Interface layer can be an oxide as disclosed herein. Interface layer can also be formed of, for example, one or more of SiO₂, Si₃N₄, Al₂O₃, and W. Interface layer can have a thickness of about 300 nm or less. In various embodiments, interface layer can have a thickness of about 1 nm to about 10 nm.

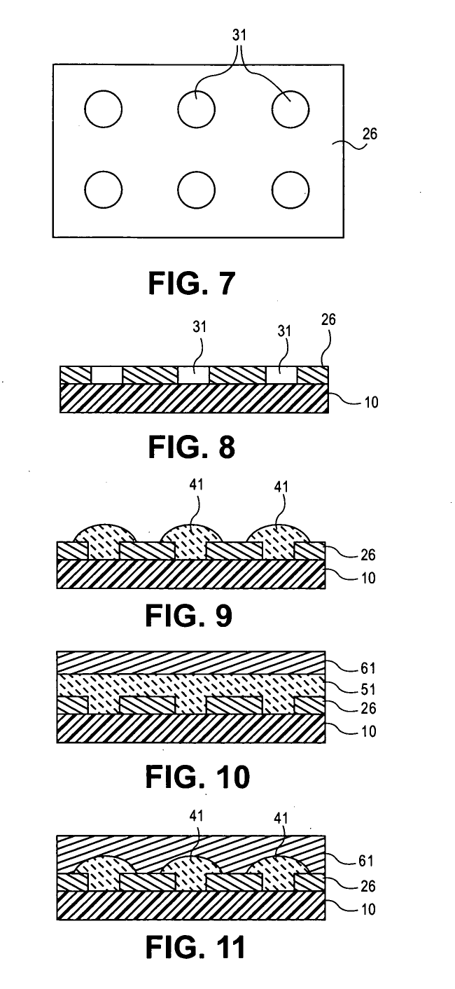

As shown in the top view of FIG. 7, a template 26 can be formed from interface layer 20 using interferometric lithography. For example, template 26 can be formed by patterning interface layer 20 to include a plurality of periodic touchdown windows 31 arranged in an array. Plasma etching can then be used to expose portions of substrate 10. FIG. 8 shows a cross-sectional view of touchdown windows 31, where each touchdown window exposes a portion of substrate 10. In various embodiments, touchdown windows 31 can have a diameter of 200 nm or less. In various other embodiments, touchdown windows 31 can have a diameter, on the order of ^{λ/[n Sinθ]}, where λ, n, and θ denote the wavelength of a laser line used to expose the photoresist, the refractive index of the medium through which the laser line travels, and the angle of incidence for the laser on the exposed substrate. Thus, the shorter the laser line wavelength, the smaller the feature that can be created. Moreover, interferometric lithography can enable access to features that are smaller than the diffraction limit of light to which the photoresist is exposed. In various embodiments, one can even go further to smaller dimensions, utilizing immersion lithography where the sample is immersed in a liquid where n greater than 1. For example, using about a 355 nm laser line, features can be created that are close to 200 nm or smaller.

After forming template 26, template 26 and the exposed portions of substrate 10 can be exposed to a material comprising a semiconductor material. Exposure temperatures can be about 500°0 C. to about 750° C. The semiconductor material can comprise, for example, germanium (Ge). In various embodiments, molecular beam epitaxy can be used to expose template 26 and the exposed portions of substrate 10 to Ge. Due to selective deposition, Ge can deposit on the exposed portions of substrate 10, but there is generally little or no deposition on template 26. As exposure to Ge continues, Ge growth on exposed portions of substrate 10 can form crystalline Ge islands 41, also referred to herein as seed pads, as shown in FIG. 9. Seed pads can then laterally overgrow and coalesce to form a semiconductor layer 51, as shown in FIG. 10. In various embodiments, a diameter of touchdown windows 31 can be made as small as possible by interferometric lithography or immersion lithography, utilizing the shortest wavelength laser possible.

Semiconductor layer 51 can be virtually defect-free having a threading dislocation density of about 1×10⁵ cm⁻² or less. Stacking faults can exist over the surface of the remaining template 26, but generally terminate within about 80 nm from the interface, for example, the SiO₂-Ge interface. As shown in FIG. 10, a layer 61 can be formed on ELO layer 51. In various embodiments, layer 61 can comprise at least one element from Groups III-V and II-VI.

In various embodiments, layer 61 can be formed on template 26 prior to coalescing of islands 41 into a continuous layer. As shown in FIG. 11, islands 41 have grown within touchdown windows 31 of template 26, but have not coalesced into a continuous layer. Layer 61 can then be formed on template 26 and islands 41. In various embodiments, layer 61 can be a layer having a more substantial lattice mismatch with islands 41, such as, for example, where islands 41 comprise Ge and layer 61 comprises GaN or HgCdTe.

### EXAMPLE 2

In an exemplary embodiment, a Ge epilayer was formed on a silicon . substrate using a template as disclosed herein. Referring back to FIGS. 1 and 7-10, a silicon substrate 10 was formed by dicing an undoped Si(100) wafer. A SiO₂ interface layer 20 was thermally grown on substrate 10 by dry oxidation. SiO₂ interface layer 20 had a thickness of about 300 nm. A template 26 was then formed by patterning a two dimensional array of touchdown windows (or vias) in SiO₂ interface layer 20. Interferometric lithography by a 355 nm Ar laser line and plasma etching was used to form an array of touchdown windows 31 in template 26, exposing portions of underlying substrate 10. Touchdown windows 31 had an average depth of about 300 nm and an average diameter of about 200 nm.

Contaminants were removed from the surface of silicon substrate 10 and template 26 by immersion in a Piranha solution for about 20 minutes. The Piranha solution was prepared by mixing 4 volumetric parts of 2M H₂SO₄ with 1 volumetric part of 30 wt % H₂O₂. Because the Piranha solution is an oxidant, a SiO₂ layer formed on the exposed portions of silicon substrate 10. Silicon substrate 10 and template 25 were then rinsed with deionized water, dried with N₂ gas, and placed in an ultrahigh vacuum (UHV) molecular beam epitaxy (MBE) chamber. The base pressure of the UHV chamber was about 4×10⁻¹⁰ Torr. Silicon substrate 10 and template 25 were heated to about 900° C. to remove contaminants and to partially remove the oxide formed by the Piranha treatment. The temperature was then reduced to about 650° C. Ge exposure was provided by a Ge Knudsen effusion cell operated at about 1120° C. for a Ge growth rate of about 0.7 ML/min.

The Ge exposure created a plurality of Ge islands within touchdown windows 31. As shown in FIG. 10, further exposure to Ge resulted in the islands growing over the top of touchdown windows 31 and coalescing into Ge epilayer 51. Ge epilayer 51 was a fully relaxed, single crystalline layer having a dislocation density of less than about 10⁵ cm⁻².

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method of forming a semiconductor device comprising:
forming an interface layer on a substrate;
forming a plurality of touchdown windows in the interface layer using one of interferometric lithography and immersion lithography, wherein each of the touchdown windows expose a portion of the substrate;
exposing the exposed portions of the substrate to a material comprising a semiconductor material; and
forming an island comprising the semiconductor material on each of the exposed portions of the substrate.

2. The method of claim 1 further comprising:
laterally growing islands over the interface layer to form a first layer comprising the semiconductor material; and
forming a second layer on the first layer, wherein the second layer comprises at least one element from Groups III-V and II-VI.

3. The method of forming a semiconductor device of claim 1, wherein the step of forming an interface layer comprises oxidizing the substrate.

4. The method of forming a semiconductor device of claim 1, wherein the step of forming a plurality of touchdown windows using interferometric lithography comprises:
patterning the interface layer using a laser; and
plasma etching the interface layer to form the plurality of touchdown windows.

5. The method of forming a semiconductor device of claim 2, wherein the first layer comprises a threading dislocation density of about 1×10⁵ cm⁻² or less.

6. The method of forming a semiconductor device of claim 1, wherein the substrate comprises silicon and the semiconductor material comprises germanium.

7. The method of forming a semiconductor device of claim 1, wherein an average touchdown window diameter is 200 nm.

8. The method of forming a semiconductor device of claim 2, wherein the first layer comprises a single crystal epitaxial layer.

9. The method of forming a semiconductor device of claim 1, wherein the interface layer comprises one or more of SiO₂, Si₃N₄, Al₂O₃, and W.

10. A method of forming an epitaxial overgrowth layer comprising:
forming an interface layer on a substrate;
using one of interferometric lithography and immersion lithography to form a periodic pattern on the interface layer;
plasma etching the periodically patterned interface layer to form a template that exposes portions of the substrate;
selectively growing germanium islands on the substrate through openings of the template using molecular beam epitaxy; and
coalescing the germanium islands to form a single crystal expitaxial overgrowth layer.

11. The method of claim 10, wherein the expitaxial overgrowth layer has a threading dislocation density of about 1×10⁵ cm⁻² or less.

12. The method of claim 11, further comprising forming a second layer on the expitaxial overgrowth layer, wherein the second layer comprises one or more elements from Groups III-V and II-VI.

13. The method of claim 10, wherein the step of patterning the interface layer using interferometric lithography.

14. The method of claim 13, wherein each touchdown window is about 200 nm in diameter and about 300 nm deep.

15. The method of forming a semiconductor device of claim 10, wherein the interface layer comprises one or more of SiO₂, Si₃N₄, Al₂O₃, and W.

16. The method of forming a semiconductor device of claim 10, wherein the interface layer is about 300 nm thick.

17. A semiconductor device comprising:
a substrate;
a template disposed on the substrate, wherein the template comprises a periodic pattern that exposes portions of the substrate;
an epitaxial layer disposed over the template and contacting the exposed portions of the substrate; and
a layer disposed on the epitaxial layer, wherein the layer comprises at least one element from Groups III-V and II-VI.

18. The semiconductor device of claim 17, wherein the epitaxial layer comprises a threading dislocation density of less than 1×10⁵ cm⁻².

19. The semiconductor device of claim 17, wherein the template has a thickness of about 300 nm or more.

20. The semiconductor device of claim 17, wherein the periodic pattern comprises a plurality of circular touchdown windows having a diameter of about 200 nm or less.

21. The method of claim 1 further comprising forming a layer comprising at least one element from Groups III-V and II-VI on the interface layer and the islands.
